(19) United States
(12) Patent Application Publication
(10) Pub. No.: US 2025/0065429 A1
(43) Pub. Date: Feb. 27, 2025

(54) MOUNTING SYSTEM AND MEMBER REPLENISHMENT GUIDANCE METHOD

(71) Applicant: FUJI CORPORATION, Chiryu (JP)

(72) Inventor: Kenji NAKAI, Anjo-shi (JP)

(73) Assignee: FUJI CORPORATION, Chiryu (JP)

(21) Appl. No.: 18/724,245

(22) PCT Filed: Jan. 26, 2022
(86) PCT No.: PCT/JP2022/002810

§ 371 Date: Jun. 26, 2024

(51) Int. Cl. B23K 1/00; B23K 31/02; B23K 37/04

(52) U.S. Cl. CPC B23K 1/0008; B23K 31/02; B23K 37/04

(57) ABSTRACT

A mounting system formed by arranging multiple mounting devices, on which multiple members used in a mounting process of a board are mounted, along a conveyance direction of the board, the mounting system includes: an information acquisition section configured to acquire information including a conveyance status of the board; and a guidance output section configured to, when replenishment of the members is required or is predicted to be required in two or more mounting devices, determine which mounting device is to be preferentially replenished based on the conveyance status of the board and output the determined replenishment guidance.

### TECHNICAL FIELD

The present description discloses a mounting system and a member replenishment guidance method.

### BACKGROUND ART

Conventionally, there is known a mounting system in which multiple mounting devices, on which members such as component supply units used in mounting process of a board are mounted, are arranged along a conveyance direction of the board (for example, refer to Patent Literature 1). This mounting system includes an operation device (exchange device) that performs automatic exchange operation of members required for production, and provides an operation instruction guidance to an operator by considering an operational status of the operation device, thereby promoting cooperative operation of exchange operation by the operator and exchange operation by the operation device, and improving efficiency of the exchange operation of the members.

### PATENT LITERATURE

Patent Literature 1: WO2021/186552A1

### BRIEF SUMMARY

### Technical Problem

Here, there may be a case where two or more mounting devices require replenishment of members at the same time. In this case, the production of the board is interrupted until members required for each mounting device are replenished. Therefore, depending on the order in which the members are replenished, the production interruption time due to waiting for the replenishment of the members may be prolonged, potentially decreasing production efficiency.

A main object of the present disclosure is to efficiently replenish members when two or more mounting devices require replenishment of the members.

### Solution to Problem

The present disclosure employs the following means in order to achieve the main object described above.

A mounting system of the present disclosure is summarized as a mounting system formed by arranging multiple mounting devices, on which multiple members used in a mounting process of a board are mounted, along a conveyance direction of the board, the mounting system including:

an information acquisition section configured to acquire information including a conveyance status of the board; and

a guidance output section configured to, when replenishment of the members is required or is predicted to be required in two or more mounting devices, determine which mounting device is to be preferentially replenished based on the conveyance status of the board and output the determined replenishment guidance.

The mounting system of the present disclosure determines, when replenishment of the members is required or is predicted to be required in two or more mounting devices, which mounting device is to be preferentially replenished based on the conveyance status of the board and outputs the determined replenishment guidance. Therefore, it is possible to output the replenishment guidance to prevent the influence of waiting for replenishment of the members by considering the conveyance status of the board. Accordingly, when two or more mounting devices require replenishment of the members, it is possible to efficiently replenish the members.

### BRIEF DESCRIPTION OF DRAWINGS

FIG. 1 is a view schematically illustrating a configuration of mounting system 10.

FIG. 2 is a view schematically illustrating a configuration of mounting device 20.

FIG. 3 is a block diagram illustrating a configuration related to control of mounting system 10.

FIG. 4 is a diagram illustrating an example of feeder information 54a and board information 54b.

FIG. 5 is a flowchart illustrating an example of a feeder replenishment-related process.

FIG. 6 is a flowchart illustrating an example of a target lane setting process.

FIG. 7 is a view illustrating an example of a conveyance status of board S.

FIG. 8 is a flowchart illustrating an example of a replenishment guidance output process.

FIG. 9 is a view illustrating an example of determining mounting device 20 to be preferentially replenished.

FIG. 10 is a view illustrating an example of determining mounting device 20 to be preferentially replenished.

FIG. 11 is a view illustrating an example of determining mounting device 20 to be preferentially replenished.

FIG. 12 is a flowchart illustrating an example of a removal guidance process.

FIG. 13 is a flowchart illustrating a feeder replenishment-related process according to a modification example.

### DESCRIPTION OF EMBODIMENTS

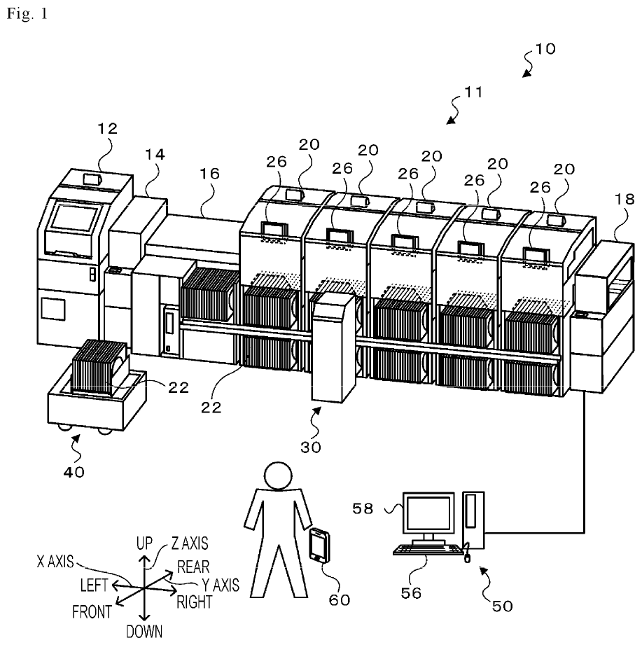

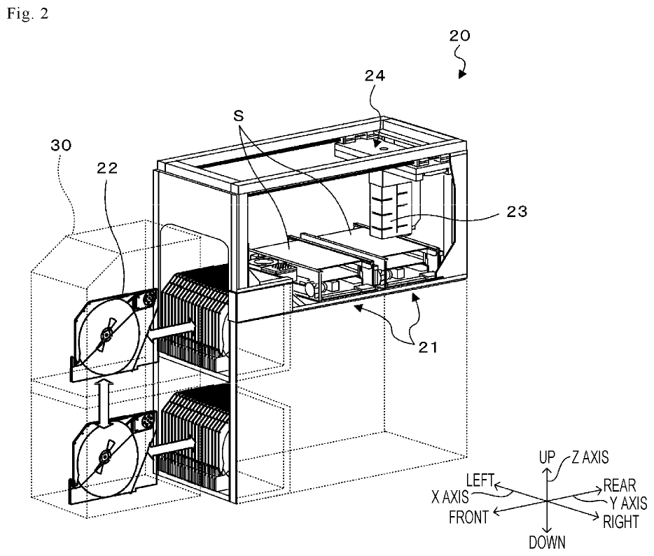

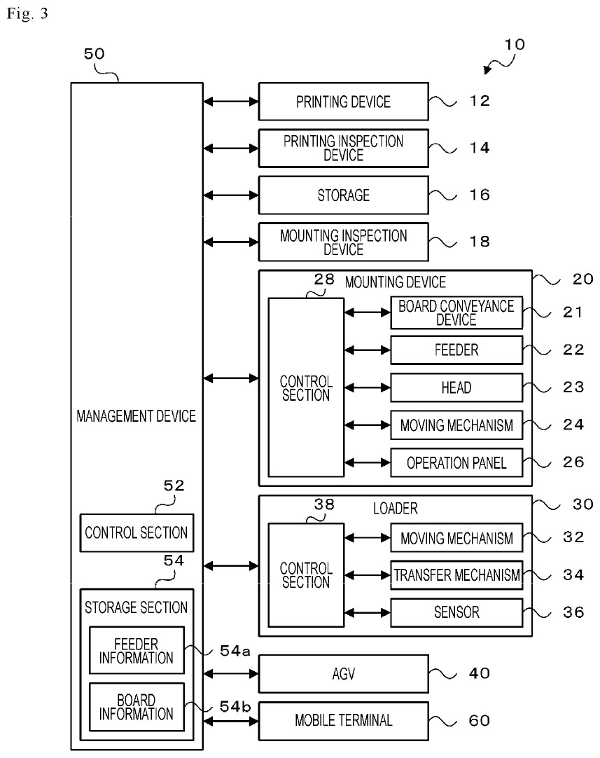

Next, an embodiment of the present disclosure will be described with reference to the drawings. FIG. 1 is a view schematically illustrating a configuration of mounting system 10. FIG. 2 is a view schematically illustrating a configuration of mounting device 20. FIG. 3 is a block diagram illustrating a configuration related to control of mounting system 10. In the present embodiment, a left-right direction (X axis), a front-rear direction (Y axis), and an up-down direction (Z axis) are as illustrated in FIGS. 1 and 2.

Mounting system 10 performs a mounting process of components on boards S (refer to FIG. 2) and includes mounting line 11, loader 30, automated guided vehicle 40 (hereinafter, AGV 40), and management device 50. Mounting line 11 includes printing device 12, printing inspection device 14, storage 16, mounting device 20, and mounting inspection device 18. These are arranged in a conveyance direction of board S (an X-axis direction). Mounting line 11 may include a reflow device or the like that performs a reflow process of board S on which the components are mounted.

Printing device 12 prints on board S by pushing solder into pattern holes formed in a screen mask. Printing inspection device 14 inspects a state of the solder printed by printing device 12. Mounting inspection device 18 inspects a mounting state of components mounted on board S by mounting device 20.

Multiple mounting devices 20 are arranged along the conveyance direction of board S and mount components on board S. Mounting device 20 includes board conveyance device 21, multiple feeders 22, head 23, moving mechanism 24, operation panel 26, and control section 28. Board conveyance device 21 has two pairs of conveyor belts and conveys board S by each conveyor belt. Therefore, mounting line 11 can convey board S in two conveyor lanes parallel to each other, one in front and one behind. The two conveyor lanes are referred to as conveyor lanes L1 and L2, respectively.

Feeder 22 is configured as a tape feeder that has a reel on which a tape holding a component in a predetermined pitch is wound and which feeds out the tape to supply the component by rotating the reel. Feeder 22 is detachably mounted on a loading table provided on the front surface of mounting device 20, and multiple feeders 22 are arranged and held in the X-axis direction. Head 23 is configured with pickup members such as nozzles, which can be lifted and lowered, and uses the pickup members to pick up a component and mount the component on board S. Moving mechanism 24 includes a slider that moves in an XY direction guided by guide rails, and a motor that drives the slider, and moves head 23 attached to the slider in the XY direction. Operation panel 26 includes a display section that displays various information and an operation section on which various types of input operations can be performed by an operator.

Control section 28 is configured with a well-known CPU, ROM, RAM, and the like, and outputs drive signals to board conveyance device 21, each feeder 22, head 23, moving mechanism 24, and the like, and outputs display signals to operation panel 26. Control section 28 receives signals from board conveyance device 21, each feeder 22, head 23, moving mechanism 24, and the like, and receives operation signals from operation panel 26.

Storage 16 is an in-line storage for storing feeders 22 used in the mounting process in mounting line 11. The operator replenishes or retrieves feeders 22 in storage 16. Further, in storage 16, loader 30 and AGV 40 are configured to automatically exchange feeders 22, and can replenish or retrieve feeders 22. AGV 40 is configured to travel automatically between mounting line 11 and the warehouse of feeders 22 and convey feeders 22.

Loader 30 includes moving mechanism 32, transfer mechanism 34, sensor 36, and control section 38. Moving mechanism 32 is configured to move loader 30 in the left-right direction along the conveyance direction of board S on the front surface side of multiple mounting devices 20 and storage 16. Although not illustrated, transfer mechanism 34 includes a clamp mechanism for clamping feeder 22, a clamp moving mechanism for moving the clamp mechanism in the front-rear direction or the up-down direction, and is configured to transfer feeder 22 between loader 30 and mounting device 20 or storage 16. As sensor 36, a detection sensor that detects an operator or an object within a predetermined detection range in the advancement direction (left direction or right direction) of loader 30, a position sensor that detects a movement position, or the like is provided.

Control section 38 is configured with a well-known CPU, ROM, RAM, and the like, receives various detection signals from sensor 36, and outputs drive signals to moving mechanism 32 and transfer mechanism 34. When feeder 22 is automatically exchanged, control section 38 causes moving mechanism 32 to move loader 30 at a position facing mounting device 20 having feeder 22 to be exchanged as a target position. When loader 30 arrives at the target position, control section 38 causes transfer mechanism 34 to pull out and retrieve feeder 22 mounted on mounting device 20. Further, control section 38 causes transfer mechanism 34 to feed out new feeder 22 in loader 30 and mount new feeder 22 on mounting device 20. When an obstacle such as an operator or an object is detected by sensor 36 during traveling of loader 30, control section 38 causes moving mechanism 32 to stop traveling of loader 30 until the obstacle is no longer detected.

Management device 50 is a general-purpose computer including control section 52 configured with a well-known CPU, ROM, RAM, and the like, and storage section 54 such as HDD that stores various information, with input device 56 such as a keyboard or a mouse and output device 58 such as a display connected. Storage section 54 stores feeder information 54a and board information 54b in addition to the production program for board S. The production program includes information such as the production quantity of board S, the printing position of solder on board S, and the type, mounting position, and the mounting order of the component to be mounted on board S. When producing board S, management device 50 outputs various command signals to the respective devices such as printing device 12, printing inspection device 14, mounting device 20, and mounting inspection device 18 based on the production program, and inputs the production status from the respective devices. Further, management device 50 outputs replenishment guidance for replenishing feeder 22 to mounting device 20 to loader 30, and inputs an operational status of loader 30. Management device 50 is configured to wirelessly communicate with AGV 40, outputs a traveling instruction to AGV 40, and inputs a traveling status of AGV 40. Management device 50 is configured to communicate with mobile terminal 60 carried by an operator, outputs various information displayed on the display screen of mobile terminal 60, and inputs information input by mobile terminal 60 or information read by mobile terminal 60.

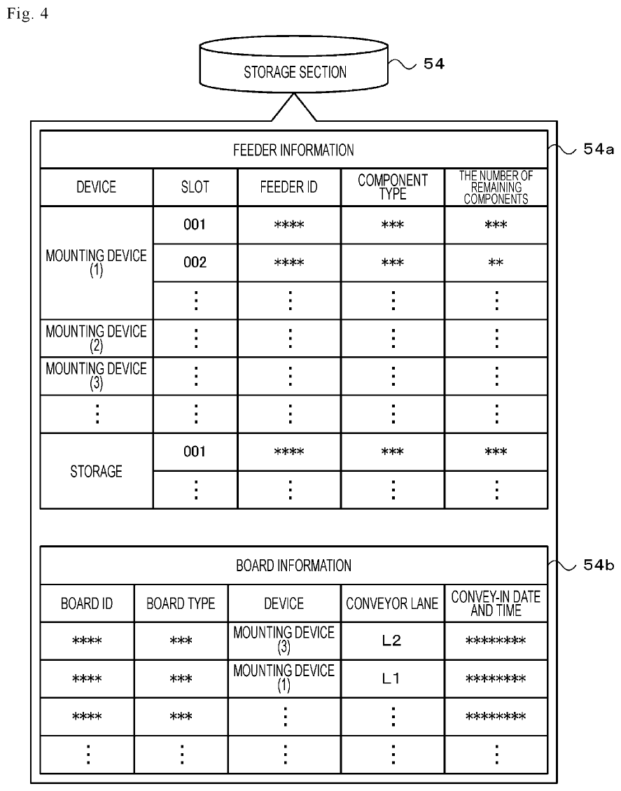

Here, FIG. 4 is a diagram illustrating an example of feeder information 54a and board information 54b. Feeder information 54a includes information relating to an arrangement position of feeder 22, a feeder ID which is identification information of feeder 22, a component type and the number of remaining components accommodated in feeder 22, and the like. The information on the arrangement position includes information on which of mounting device 20 and storage 16 is feeder 22 arranged in, and which slot is feeder 22 mounted in. Board information 54b includes a board ID which is identification information of board S, which is present in mounting line 11, that is, board S being produced, a board type, information related to the presence position of board S, a convey-in date and time of board S, and the like. The information on the presence position includes information on the device and the conveyor lane where board S is present. The convey-in date and time is information on the date and time when board S was conveyed into leading mounting device 20(1) of the conveyor lane where board S is present. Management device 50 appropriately updates feeder information 54a and board information 54b through communication with each device, storage 16, or the like.

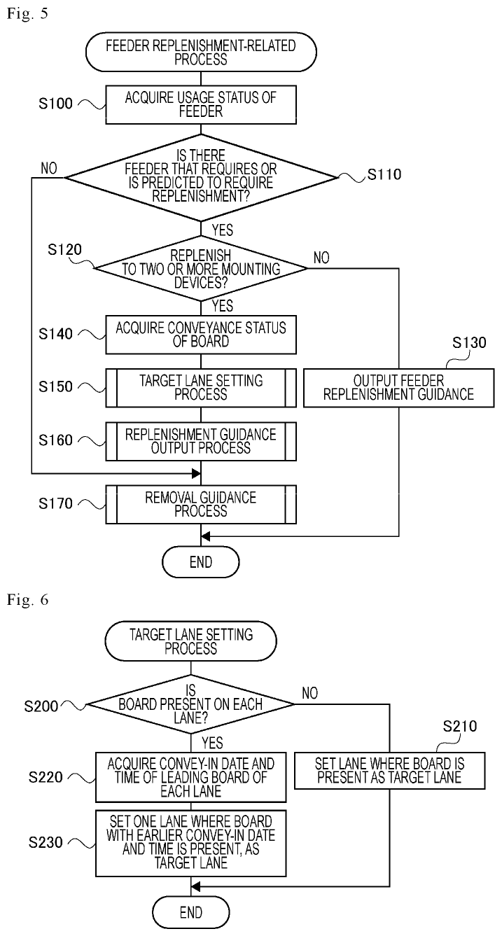

The following is a description of the operation of mounting system 10 configured as above. FIG. 5 is a flowchart illustrating an example of a feeder replenishment-related process. This process is executed by control section 52 of management device 50. In the replenishment-related process, control section 52 first acquires the usage status of feeder 22 (S100). For example, control section 52 acquires information on the number of remaining components of each feeder 22 from feeder information 54a as the usage status of feeder 22.

Next, control section 52 determines, based on the usage status of feeder 22, whether there is feeder 22 that requires replenishment (exchange) or there is feeder 22 that is predicted to require replenishment in any of mounting devices 20(S110). For example, feeder 22 that requires replenishment is feeder 22 in which the number of remaining components is 0, indicating component depletion, and feeder 22 that is predicted to require replenishment is feeder 22 in which the number of remaining components is equal to or less than a predetermined number in the vicinity of 0, indicating that component depletion is imminent. In addition, control section 52 may acquire the production status of each device in S100 to predict the changeover of board types, and determine whether there is feeder 22 that is predicted to require replenishment due to the setup change accompanying the changeover. When control section 52 determines in S110 that there is no feeder 22 that requires or is predicted to require replenishment, the process proceeds to S170.

On the other hand, when it is determined that there is feeder 22 that requires or is predicted to require replenishment, control section 52 determines whether to replenish feeder 22 to two or more mounting devices 20(S120). When it is determined that feeder 22 is replenished to one mounting device 20 instead of two or more mounting devices, control section 52 outputs replenishment guidance of feeder 22 required for mounting device 20(S130), and ends the replenishment-related process. The replenishment guidance in S130 is output to loader 30, and includes the identification number (module number) of mounting device 20 that requires replenishment, the feeder ID and the slot number of feeder 22, the feeder ID and the slot number of replenishment target feeder 22 in storage 16, and the like. Loader 30 that has received the replenishment guidance moves to storage 16, takes out replenishment target feeder 22 from storage 16, and then moves to replenishment target mounting device 20. Then, loader 30 removes feeder 22 that requires replenishment from replenishment target mounting device 20, and then attaches replenishment target feeder 22, thereby performing replenishment (exchange) of feeder 22. The replenishment guidance in S130 may be output to mobile terminal 60 of the operator.

When it is determined that replenishment of feeder 22 for two or more mounting devices 20 is required, that is, there are two or more replenishment target mounting devices 20 that require replenishment of feeder 22 at the same time, control section 52 acquires the conveyance status of board S from board information 54b (S140). Subsequently, since control section 52 determines, based on the conveyance status of board S, which mounting device 20 to prioritize for replenishment and replenishes feeder 22 accordingly, control section 52 performs a target lane setting process (S150) and replenishment guidance output process (S160).

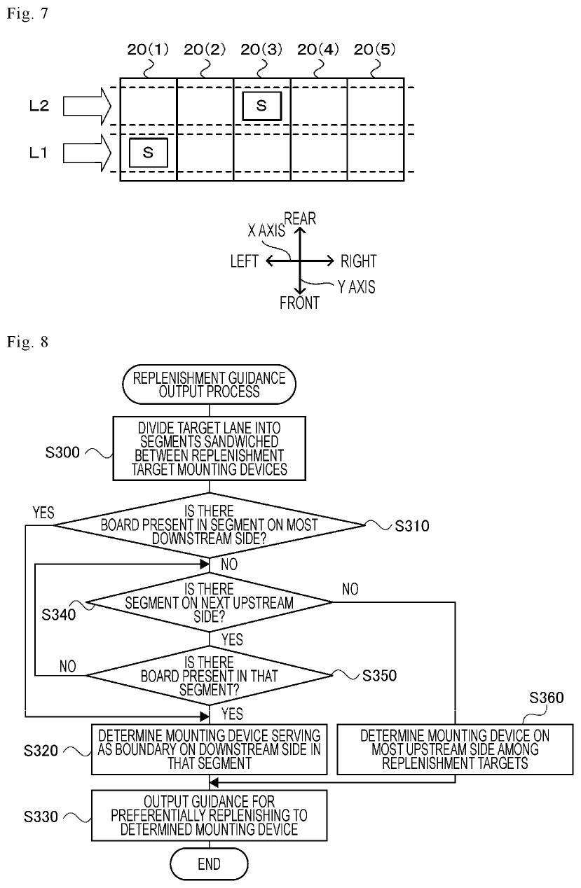

FIG. 6 is a flowchart illustrating an example of a target lane setting process. FIG. 7 is a view illustrating an example of a conveyance status of board S. In this process, control section 52 determines whether board S is present in each of the conveyor lanes (conveyor lanes L1 and L2) based on the conveyance status of board S acquired in S140 (S200). When it is determined that board S is present only in any one of the conveyor lanes, control section 52 sets the conveyor lane where board S is present as the target lane (S210), and ends the target lane setting process.

On the other hand, when it is determined that board S is present in each conveyor lane, control section 52 acquires, from board information 54b, information on the convey-in date and time when board S positioned at the head (most downstream side) of each conveyor lane was conveyed into leading mounting device 20(1) (S220). Subsequently, control section 52 specifies board S having the earliest convey-in date and time, sets one conveyor lane where board S is present as the target lane (S230), and ends the target lane setting process. In FIG. 7, when the convey-in date and time of board S in mounting device 20(3) is earlier, conveyor lane L2 is set as the target lane. In addition, when the convey-in date and time of board S in mounting device 20(1) is earlier although the conveyance is delayed due to component depletion or the like, conveyor lane L1 is set as the target lane. Although board information 54b includes the convey-in date and time, board information 54b may be sufficient to specify board S conveyed earliest, and may at least include the convey-in time. Alternatively, the elapsed time since board S was conveyed may be included in board information 54b, and control section 52 may specify board S conveyed earliest based on the elapsed time.

FIG. 8 is a flowchart illustrating an example of a replenishment guidance output process. In this process, first, control section 52 divides the target lane set in the target lane setting process, with mounting device 20 which is a replenishment target of feeder 22 serving as a boundary, into one or more segments sandwiched between mounting devices 20 serving as the boundaries (S300). Next, control section 52 determines whether board S is present in the segment on the most downstream side among the divided segments (S310), and when it is determined that board S is present, control section 52 determines mounting device 20 serving as the boundary on the downstream side in that segment, here, the segment on the most downstream side (S320). Subsequently, control section 52 outputs replenishment guidance for preferentially replenishing feeder 22 to determined mounting device 20 to loader 30 (S330), and ends the replenishment guidance output process. The replenishment guidance in S330 may be output to mobile terminal 60 of the operator.

On the other hand, when it is determined in S310 that board S is not present in the segment on the most downstream side, control section 52 determines whether there is a segment on the next upstream side to that segment (S340). When it is determined that there is a segment on the next upstream side, control section 52 determines whether board S is present in that segment (S350). That is, control section 52 subsequently determines whether board S is present in each segment from the segment on the most downstream side in the target lane. When it is determined that board S is present in the segment on the upstream side, control section 52 determines mounting device 20 serving as the boundary on the downstream side in that segment (S320), outputs the replenishment guidance for preferentially replenishing feeder 22 to mounting device 20(S330), and ends the replenishment guidance output process.

Further, when it is determined in S340 that there is no segment on the upstream side, that is, board S is not present in any of the segments sandwiched between replenishment target mounting devices 20, control section 52 determines mounting device 20 on the most upstream side among replenishment target mounting devices 20(S360). Subsequently, control section 52 outputs replenishment guidance for preferentially replenishing feeder 22 to determined mounting device 20(S330), and ends the replenishment guidance output process.

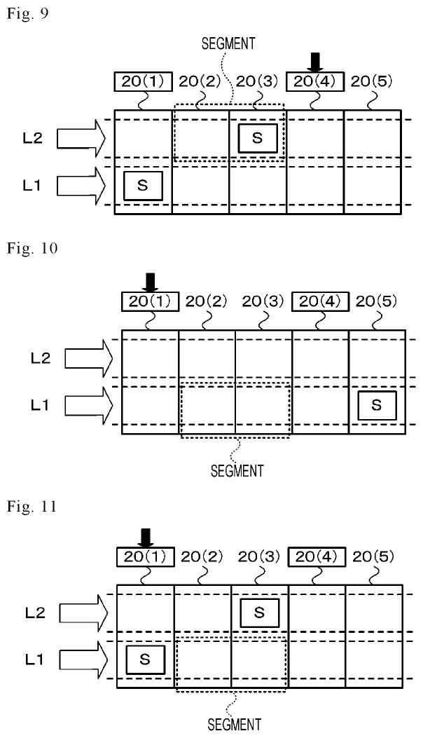

Here, FIGS. 9 to 11 are views illustrating examples of determining mounting device 20 to be preferentially replenished. In FIGS. 9 to 11, the replenishment targets are mounting device 20(1) and mounting devices 20(4), and it is determined whether board S is present in one segment with mounting device 20(1) and mounting device 20(4) serving as boundaries, that is, in mounting device 20(2) and mounting device 20(3). In addition, it may be determined whether board S is present in mounting device 20(2) to mounting device 20(4), including mounting device 20(4) serving as the boundary on the downstream side in that segment. Further, the replenishment target is not limited to two mounting devices 20, and may be two or more mounting devices 20.

In FIG. 9, since the target lane is conveyor lane L2 and it is determined that board S of mounting device 20(3) is present in the segment, in S320, mounting device 20(4) serving as the boundary on the downstream side in the segment is determined as the prioritized replenishment target, and feeder 22 is replenished. When feeder 22 is replenished to mounting device 20(1) first, the time during which board S in mounting device 20(3) waits for the replenishment of feeder 22 to mounting device 20(4) becomes long, and the process is delayed. Due to the influence of the delay, even when new board S is conveyed into conveyor lane L2 and processed, it may remain without promptly being conveyed to the downstream side. Here, mounting device 20 serving as the boundary on the downstream side in the segment where board S is present is determined as the prioritized replenishment target, and feeder 22 is replenished. Accordingly, it is possible to prevent a delay in processing board S in the segment and efficiently perform the production of board S.

On the other hand, in FIG. 10, since the target lane is conveyor lane L1 and it is determined that board S is not present in the segment, in S360, mounting device 20(1) on the most upstream side among the replenishment targets is determined as the prioritized replenishment target and feeder 22 is replenished. This is because, when board S is not present in the segment, feeder 22 is required first in mounting device 20 on the upstream side in the processing of next conveyed board S. As a result, it is possible to prevent next conveyed board S from waiting for replenishment of feeder 22 to mounting device 20(1), and to efficiently produce board S.

Further, in FIG. 11, although the conveyance is delayed, conveyor lane L1 is set as the target lane because the convey-in date and time of board S in mounting device 20(1) is earlier. Therefore, since it is determined that board S is not present in the segment, mounting device 20(1) is determined as the prioritized replenishment target, and feeder 22 is replenished. In the case of FIG. 11, it is also conceivable to make conveyor lane L2 the target lane simply because board S is positioned on the downstream side, and make mounting device 20(4) the prioritized replenishment target because board S is present in the segment. However, when the processing of board S in conveyor lane L2 is prioritized, the processing of board S in conveyor lane L1, which was conveyed earlier, is further delayed due to waiting for replenishment of feeder 22. When such situation continues, the imbalance in the progress of production of conveyor lanes L1 and L2 increases, which is not preferable. Here, prioritized replenishment target mounting device 20 is determined based on the conveyance status of one conveyor lane into which board S was conveyed earlier, and feeder 22 is replenished.

In the feeder replenishment-related process of FIG. 5, when control section 52 executes the target lane setting process (S150) and the replenishment guidance output process (S160), control section 52 then executes the removal guidance process (S170), and ends the feeder replenishment-related process. Here, the replenishment guidance in S330 is also output to mobile terminal 60 of the operator, and there may be a case where the operator manually replenishes feeder 22. In this case, there may be a case where the operator first replenishes feeder 22 to mounting device 20 having a low degree of priority (mounting device 20 different from the instruction) other than prioritized replenishment target mounting device 20, and handling for this situation is performed in S170.

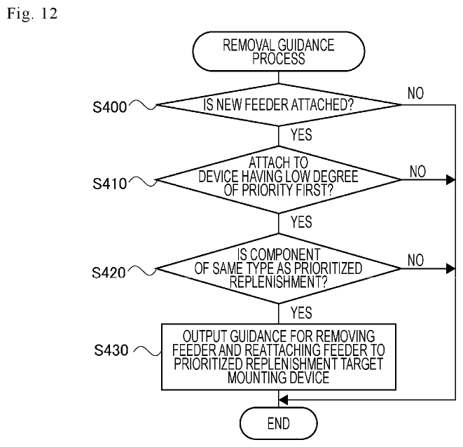

FIG. 12 is a flowchart illustrating an example of a removal guidance process. In this process, when control section 52 first determines whether new feeder 22 is attached (S400), and determines new feeder 22 is not attached, ends the removal guidance process. When it is determined that new feeder 22 is attached, control section 52 determines whether new feeder 22 is first attached to mounting device 20 having a low degree of priority (S410), and determines whether feeder 22 of the same type of component as preferentially replenished feeder 22 is attached (S420). When a negative determination is made in either S410 or S420, control section 52 ends the removal guidance process.

When control section 52 determines that feeder 22 of the same type of component is attached to mounting device 20 having a low degree of priority in S410 and S420, control section 52 removes feeder 22, outputs guidance for reattaching feeder 22 to prioritized replenishment target mounting device 20(S430), and ends the removal guidance process. In the guidance, information that feeder 22 was mistakenly attached first to mounting device 20 having a low degree of priority, the module number and the slot number of mounting device 20 from which feeder 22 is to be removed, and the module number and the slot number of mounting device 20 to which feeder 22 is to be attached are output. Accordingly, even when feeder 22 is first attached to mounting device 20 having a low degree of priority, feeder 22 can be properly replenished to prioritized replenishment target mounting device 20.

Here, a correspondence relationship between elements of the present embodiment and elements of the present disclosure will be clarified. Mounting system 10 of the present embodiment corresponds to a mounting system of the present disclosure, control section 52 of management device 50 that executes S140 of the feeder replenishment-related process corresponds to an information acquisition section, and control section 52 that executes S160 of the same process corresponds to a guidance output section. In the present embodiment, an example of a member replenishment guidance method is also clarified by describing an operation of mounting system 10.

In mounting system 10 described above, control section 52 determines which of two or more replenishment target mounting devices 20 to preferentially replenish feeder 22 based on the conveyance status of board S. Therefore, since the replenishment guidance can be output to prevent the influence of waiting for replenishment of feeder 22 by considering the conveyance status of board S, feeder 22 can be efficiently replenished.

In addition, control section 52 divides the target lane into segments separated by the replenishment target mounting devices 20, determines whether there is a segment, where board S is present, in order from the downstream side in the conveyance direction, and causes, when there is the segment in which board S is present, mounting device 20 serving as the boundary on the downstream side in that segment to be preferentially replenished. Therefore, since the processing of board S in the segment does not proceed due to the waiting for replenishment of feeder 22, it is possible to prevent another board S from remaining on the upstream side of the segment and efficiently perform production.

In addition, when there is no segment in which board S is present, control section 52 causes mounting device 20 on the most upstream side among the replenishment targets to be preferentially replenished, and thus it is possible to efficiently replenish feeder 22 to mounting device 20 on the upstream side into which board S is next conveyed and which requires feeder 22.

In addition, control section 52 specifies board S conveyed first among boards S present in each conveyor lane and determines which mounting device 20 is to be preferentially replenished based on the conveyance status of one conveyor lane where board S is present. Therefore, when there are multiple conveyor lanes, it is possible to prevent the mounting process of board S conveyed first from being delayed.

It is needless to say that the present disclosure is not limited to the embodiment described above in any way, and hence may be implemented in various forms as long as it falls within the technical scope of the present disclosure.

For example, in the embodiment, two conveyor lanes L1 and L2 are exemplified as multiple conveyor lanes, but three or more conveyor lanes may be used. Further, although board S conveyed first among boards S present in the multiple conveyor lanes is specified, and mounting device 20 to be preferentially replenished is determined based on the conveyance status of one conveyor lane where board S is present, the present disclosure is not limited thereto. Board S present in the segment on the most downstream side among boards S present in the multiple conveyor lanes may be specified, and mounting device 20 serving as the boundary on the downstream side in that segment may be determined. The present disclosure is not limited to a configuration in which multiple conveyor lanes are provided, and one conveyor lane may be provided. In this case, since one conveyor lane is the target lane, the target lane setting process of S150 needs only be omitted.

In the embodiment, mounting device 20 on the most upstream side is to be preferentially replenished, when there is no board S present in the segment sandwiched between replenishment target mounting devices 20, but the present disclosure is not limited thereto. For example, when storage 16 is provided at a place other than upstream side in the conveyance direction, in the middle, downstream side, or elsewhere in the conveyance direction, mounting device 20 closer to storage 16 may be preferentially replenished.

In the embodiment, multiple mounting devices 20 are divided into segments, and then it is determined which mounting device 20 is to be preferentially replenished, but it may be possible to determine which mounting device 20 is to be preferentially replenished based on the conveyance status of board S without dividing into segments. For example, among two or more replenishment target mounting devices 20, it may be possible to specify mounting device 20 into which board S is conveyed next earliest and determine mounting device 20 for replenishment. However, when board S on the downstream side becomes waiting for replenishment of feeder 22, it is preferable to determine as in the embodiment because the other board S remains on the upstream side.

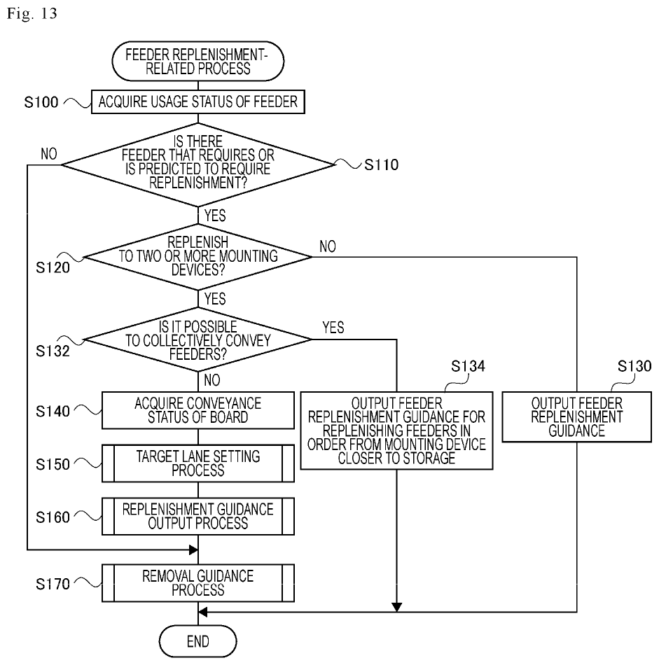

In the embodiment, mounting device 20 to be preferentially replenished is determined without considering the number of feeders 22 that loader 30 can convey at a time, but the present disclosure is not limited thereto. For example, when the number of feeders 22 that loader 30 can convey at a time is one, the process may be performed as in the embodiment, and when the number of feeders 22 is multiple, the process may be performed as in the following modification example. FIG. 13 is a flowchart illustrating a feeder replenishment-related process according to a modification example. In the modification example, the same process as in the embodiment is given the same step number, and description thereof will be omitted.

In this process, when it is determined in S120 that replenishment to two or more mounting devices 20 is required, control section 52 determines whether loader 30 can collectively (at a time) convey replenishment target feeders 22 (S132). Control section 52 makes the determination of S132, considering factors such as the maximum conveying capacity of loader 30 and the number of replenishment targets. When it is determined that loader 30 cannot collectively convey replenishment target feeders 22, control section 52 executes the process from S140 onward as in the embodiment. On the other hand, when it is determined that loader 30 can collectively convey replenishment target feeders 22, control section 52 outputs the replenishment guidance for replenishing replenishment target feeders 22 in order from mounting device 20 closer to storage 16 (S134). In other words, control section 52 determines such that mounting device 20 on the upstream side closer to storage 16 is to be preferentially replenished, among two or more replenishment target mounting devices 20.

As described above, in the modification example, when loader 30 (mobile operation device) can collectively convey feeders 22 that require replenishment, control section 52 determines such that mounting device 20 closer to storage 16 (storage section) is to be preferentially replenished regardless of the conveyance status of board S. On the other hand, when loader 30 cannot collectively convey feeders 22 that require replenishment, it is determined which mounting device 20 is to be preferentially replenished based on the conveyance status of board S. Here, when loader 30 is configured to collectively convey replenishment target feeders 22, minimizing the movement loss of loader 30 may enable more efficient replenishment of feeders 22. For example, a case may be considered, where the replenishment target includes mounting device 20 on the upstream side closer to storage 16 and mounting device 20 on the downstream side farther from storage 16. In this case, rather than loader 30 moving from storage 16 to mounting device 20 on the downstream side to replenish feeders 22 and then returning to mounting device 20 on the upstream side to replenish feeders 22, it may be more efficient to replenish in the order of mounting device 20 on the upstream side followed by mounting device 20 on the downstream side, as this may minimize movement loss and replenish efficiently. Therefore, by adopting the modification example, it is possible to efficiently replenish feeders 22 without reducing the operational efficiency (movement efficiency) of loader 30.

In the embodiment, a process of determining mounting device 20 to be preferentially replenished is performed regardless of whether the component type of replenishment target feeder 22 is the same, but the present disclosure is not limited thereto. For example, only when the component type of feeder 22 replenished to two or more mounting devices 20 is the same, the process of determining mounting device 20 to be preferentially replenished may be performed.

In the embodiment, replenishment of feeder 22 (component supply unit) is exemplified, but the present disclosure is not limited thereto, and replenishment of members used in the mounting process of the board in the mounting device may be acceptable. For example, replenishment (exchange) of heads or nozzles detachably mounted to mounting device 20 may also be acceptable. Further, it may also be acceptable for replenishment of members used in the mounting process of the board in the mounting-related devices, such as masks detachably mounted to printing device 12, not only in mounting device 20. Further, the present disclosure is not limited to a mounting system that includes loader 30 and automatically replenishes members, and a mounting system that does not include loader 30 and manually replenishes members may be used.

Here, the mounting system in the present disclosure may be configured as follows. For example, in the mounting system of the present disclosure, the guidance output section may be configured to divide the arrangement of the multiple mounting devices, with each of the two or more mounting devices serving as a boundary, into one or more segments sandwiched between the two or more mounting devices (boundary mounting devices), determine whether there is a segment, where the board is present, from a downstream side in the conveyance direction based on the conveyance status of the board, and determine, when there is the segment where the board is present, that a mounting device serving as a boundary on the downstream side in the segment is to be preferentially replenished. In this way, it is possible to prevent the influence of waiting for replenishment of the members on the board present in the segment on the downstream side in the conveyance direction. Accordingly, since the mounting process of the board on the downstream side in the conveyance direction does not proceed, it is possible to prevent another board from remaining on the upstream side of that segment, and to efficiently perform production.

In the mounting system of the present disclosure, the guidance output section may be configured to, when there is no segment where the board is present, determine that a mounting device on a most upstream side in the conveyance direction among the two or more mounting devices is to be preferentially replenished. In this way, when there is no board in the segment, it is possible to efficiently replenish the members from the mounting device on the upstream side into which the board is first conveyed and the members are required.

In the mounting system of the present disclosure, multiple conveyor lanes parallel to each other may be provided as conveyor lanes of the board extending in the conveyance direction, the information acquisition section may be configured to acquire convey-in information for specifying the board conveyed in the conveyor lanes first among the boards present in the multiple conveyor lanes, the guidance output section may be configured to specify the board conveyed in first based on the convey-in information, and determine which mounting device is to be preferentially replenished based on the conveyance status of the board in one of the conveyor lanes where the specified board is present. In this way, when there are multiple conveyor lanes, it is possible to replenish the members by considering the conveyance status of the conveyor lane where a board has been conveyed in first. Therefore, it is possible to prevent the mounting process of the board conveyed first from being delayed and to efficiently perform production.

The mounting system of the present disclosure may further include a mobile operation device configured to move along the conveyance direction between a storage section of the members and the mounting device and convey and replenish the members, in which the guidance output section may be configured to, when the mobile operation device is configured to collectively convey the members that require replenishment, determine that a mounting device close to the storage section is to be preferentially replenished regardless of the conveyance status of the board, and when the mobile operation device is not configured to collectively convey for the members that require replenishment, determine which mounting device is to be preferentially replenished based on the conveyance status of the board. In this way, it is possible to efficiently replenish required members without reducing the operational efficiency of the mobile operation device.

A member replenishment guidance method of the present disclosure is summarized as a member replenishment guidance method in a mounting system formed by arranging multiple mounting devices, on which multiple members used in a mounting process of a board are mounted, along a conveyance direction of the board, the method including: (a) a step of acquiring information including a conveyance status of the board; and (b) a step of determining, when replenishment of the members is required or is predicted to be required in two or more mounting devices, which mounting device is to be preferentially replenished based on the conveyance status of the board and outputting the determined replenishment guidance.

In the member replenishment guidance method of the present disclosure, similarly to the mounting system described above, when two or more mounting devices require replenishment of members, it is possible to efficiently replenish the members. In the member replenishment guidance method, various aspects of the mounting system described above may be adopted, or steps to achieve each function of the mounting system described above may be added.

### INDUSTRIAL APPLICABILITY

The present disclosure can be used in a mounting system or the like in which mounting devices, on which members are mounted, are arranged.

### REFERENCE SIGNS LIST

10: mounting system, 11: mounting line, 12: printing device, 14: printing inspection device, 16: storage, 18: mounting inspection device, 20: mounting device, 21: board conveyance device, 22: feeder, 23: head, 24: moving mechanism, 26: operation panel, 28, 38: control section. 30): loader. 32: moving mechanism. 34: transfer mechanism. 36: sensor. 40): automated guided vehicle (AGV). 50: management device. 52: control section. 54: storage section. 54a: feeder information. 54b: board information. 56: input device. 58: output device. 60): mobile terminal, and S: board

1. A mounting system formed by arranging multiple mounting devices, on which multiple members used in a mounting process of a board are mounted, along a conveyance direction of the board, the mounting system comprising:
an information acquisition section configured to acquire information including a conveyance status of the board; and
a guidance output section configured to, when replenishment of the members is required or is predicted to be required in two or more mounting devices, determine which mounting device is to be preferentially replenished based on the conveyance status of the board and output the determined replenishment guidance.

2. The mounting system according to claim 1,
wherein the guidance output section is configured to divide the arrangement of the multiple mounting devices, with each of the two or more mounting devices serving as a boundary, into one or more segments sandwiched between the two or more mounting devices, determine whether there is a segment, where the board is present, from a downstream side in the conveyance direction based on the conveyance status of the board, and determine, when there is the segment where the board is present, that a mounting device serving as a boundary on the downstream side in the segment is to be preferentially replenished.

3. The mounting system according to claim 1,
wherein the guidance output section is configured to, when there is no segment where the board is present, determine that a mounting device on a most upstream side in the conveyance direction among the two or more mounting devices is to be preferentially replenished.

4. The mounting system according to claim 1,
wherein multiple conveyor lanes parallel to each other are provided as conveyor lanes of the board extending in the conveyance direction,
the information acquisition section is configured to acquire convey-in information for specifying the board conveyed in the conveyor lanes first among the boards present in the multiple conveyor lanes, and
the guidance output section is configured to specify the board conveyed in first based on the convey-in information, and determine which mounting device is to be preferentially replenished based on the conveyance status of the board in one of the conveyor lanes where the specified board is present.

5. The mounting system according to claim 1, further comprising:
a mobile operation device configured to move along the conveyance direction between a storage section of the members and the mounting device and convey and replenish the members,
wherein the guidance output section is configured to, when the mobile operation device can collectively convey the members that require replenishment, determine that a mounting device close to the storage section is to be preferentially replenished regardless of the conveyance status of the board, and when the mobile operation device cannot collectively convey the members that require replenishment, determine which mounting device is to be preferentially replenished based on the conveyance status of the board.

6. A member replenishment guidance method in a mounting system formed by arranging multiple mounting devices, on which multiple members used in a mounting process of a board are mounted, along a conveyance direction of the board, the method comprising:
(a) a step of acquiring information including a conveyance status of the board; and
(b) a step of determining, when replenishment of the members is required or is predicted to be required in two or more mounting devices, which mounting device is to be preferentially replenished based on the conveyance status of the board and outputting the determined replenishment guidance.
